(19) United States
(12) Patent Application Publication
(10) Pub. No.: US 2008/0185706 A1
(43) Pub. Date: Aug. 7, 2008

(54) PACKAGE AND METHOD FOR MAKING THE SAME

(75) Inventor: Meng-Jen Wang, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 12/021,487

(22) Filed: Jan. 29, 2008

(30) Foreign Application Priority Data
Feb. 1, 2007 (TW) 096103629

(51) Int. Cl. H01L 23/48; H01L 21/00

(52) U.S. Cl. 257/690; 438/123; 257/E21.001; 257/E23.01

(57) ABSTRACT

The present invention relates to a package and a method for making the same. The package includes a substrate, a semiconductor element, and an underfill. The semiconductor element has a first surface. A plurality of bumps and at least one ring structure are disposed on the first surface, in which the bumps are outside the ring structure. The semiconductor element is disposed on the substrate through the bumps and the ring structure. The ring structure of the semiconductor element and the substrate define a closed space. The bumps electrically connect the substrate and the semiconductor element. The underfill is filled between the substrate and the semiconductor element, covering the bumps and out of the ring structure. Since the package of the present invention has the closed space, the package is not only applicable for a common flip chip package, but also for micro electro-mechanical systems (MEMS) having movable elements. In addition, a wire bonding process is not needed for the package, such that the packaging steps can be simplified so as to reduce the packaging time and the production cost.

### BACKGROUND OF THE INVENTION

1. Field of the Invention

The present invention relates to a package and a method for making the same, and more particularly to a package having a ring structure and a method for making the same.

2. Description of the Related Art

Referring to FIG. 1, a schematic view of a conventional package is shown. The conventional package 10 includes a substrate 101, a chip 102, and an underfill 103. A plurality of bumps 104 is disposed on a surface of the substrate 101. The chip 102 is disposed on the bumps 104, and is electrically connected to the substrate 101 through the bumps 104. The underfill 103 is disposed between the substrate 101 and the chip 102, and covers the bumps 104, for adhering the substrate 101 and the chip 102 and protecting the bumps 104 connected to the chip 102. The underfill 103 of the conventional package 10 completely covers the bumps 104 between the substrate 101 and the chip 102, so no space exists between the substrate 101 and the chip 102. Since the conventional package 10 does not have the space for the movement of the movable elements in a micro electro-mechanical systems (MEMS), the conventional package 10 may only be applied to a common flip chip package, but cannot be applied to any MEMS having movable elements.

Referring to FIG. 2, a schematic view of a conventional package having an MEMS microphone element is shown. The conventional package 20 includes a substrate 201, a surrounding wall 202, an MEMS microphone element 203, and an upper lid 204. The surrounding wall 202 is disposed on the substrate 201. The MEMS microphone element 203 is disposed on the substrate 201, and in a space defined by the surrounding wall 202. The MEMS microphone element 203 is electrically connected to the substrate 201 through a plurality of conductive wires 205. The upper lid 204 is disposed on the surrounding wall 202, and forms a closed space together with the substrate 201 and the surrounding wall 202.

In the prior art, a diaphragm 206 is disposed on a top surface of the MEMS microphone element 203, and the MEMS microphone element 203 is disposed with its bottom surface on the substrate 201, so as to provide a vibration space for the diaphragm 206. Further, in the conventional package 20 having an MEMS microphone element, the MEMS microphone element 203 is electrically connected to the substrate 201 through the conductive wires 205, so the packaging steps is added, which extends the packaging time and thus increasing the production cost.

Consequently, there is an existing need for providing a package and a method for making the same to solve the above-mentioned problems.

### SUMMARY OF THE INVENTION

The present invention is directed to a package. The package includes a substrate, a semiconductor element, and an underfill. The semiconductor element has a first surface, in which a plurality of bumps and at least one ring structure are disposed on the first surface, and the bumps are outside the ring structure. The semiconductor element is disposed on the substrate through the bumps and the ring structure. The ring structure of the semiconductor element and the substrate define a closed space. The bumps electrically connect the substrate and the semiconductor element. The underfill is filled between the substrate and the semiconductor element, covering the bumps and out of the ring structure.

The present invention is further directed to a method of making a package. The method includes the following steps: (a) providing a substrate; (b) providing a semiconductor element having a first surface, in which a plurality of bumps and at least one ring structure are disposed on the first surface, and the bumps are outside the ring structure; (c) disposing the semiconductor element on the substrate, in which the ring structure of the semiconductor element and the substrate define a closed space, and the bumps electrically connect the substrate and the semiconductor element; and (d) filling an underfill between the substrate and the semiconductor element, in which the underfill covers the bumps and is out of the ring structure.

In a package made by the packaging method of the present invention, a closed space is formed between the substrate and the ring structure of the semiconductor element. Therefore, the packaging method of the present invention is not only applicable to a common flip chip package, but is also applicable to a micro electro-mechanical systems (MEMS) element, since the closed space formed between the substrate and the semiconductor element may be provided for the movement of the movable elements and the diaphragm in the MEMS element.

Moreover, in the package of the present invention, the semiconductor element is directly disposed on the substrate through the bumps and the ring structure, and is electrically connected to the substrate through the bumps, so a wire bonding process is not required. Therefore, the packaging step of the present invention is simplified, thus reducing the packaging time and the production cost.

### BRIEF DESCRIPTION OF THE DRAWINGS

FIG. 1 is a schematic view of a conventional package;

FIG. 2 is a schematic view of a conventional package having an MEMS microphone element;

FIG. 3 is a schematic view showing a plurality of bumps and a ring structure disposed in a semiconductor element according to a first embodiment of the present invention;

FIG. 4 is a schematic view showing the semiconductor element disposed on a substrate according to the first embodiment of the present invention;

FIG. 5 is a schematic view of a package according to the first embodiment of the present invention;

FIG. 6 is a schematic view of a package according to a second embodiment of the present invention;

FIG. 7 is a schematic view showing a plurality of bumps and two ring structures disposed in a semiconductor element according to the second embodiment of the present invention;

FIG. 8 is a schematic view of a package according to a third embodiment of the present invention;

FIG. 9 is a schematic view of a package according to a fourth embodiment of the present invention;

FIG. 10 is a schematic view of a package according to a fifth embodiment of the present invention;

FIG. 11 is a schematic view of a package according to a sixth embodiment of the present invention;

FIG. 12 is a schematic view of a package according to a seventh embodiment of the present invention;

FIG. 13 is a schematic view of a package according to an eighth embodiment of the present invention; and

FIG. 14 is a schematic view of a package according to a ninth embodiment of the present invention.

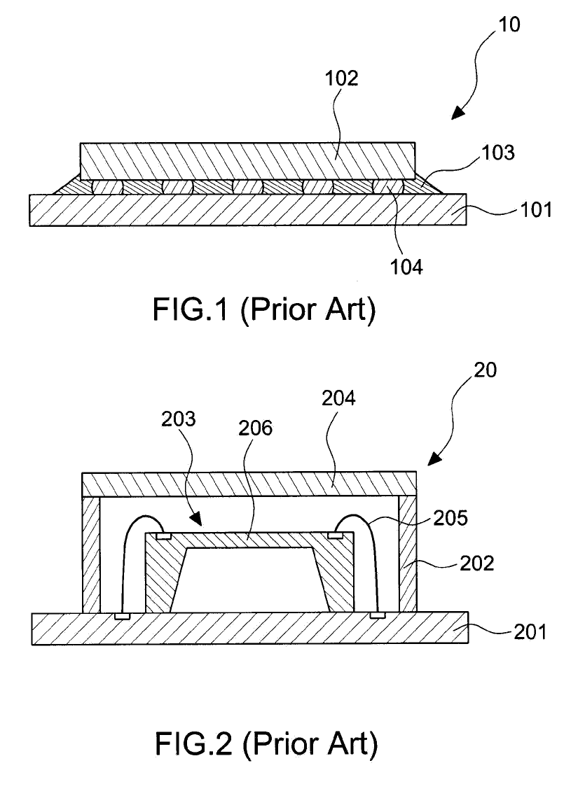

### DETAILED DESCRIPTION OF THE INVENTION

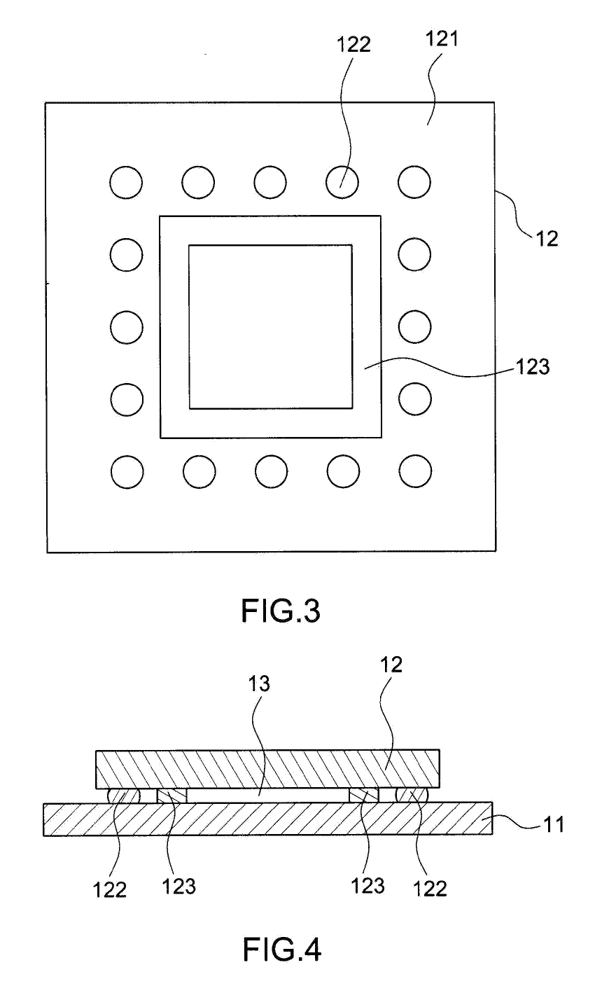

Referring to FIGS. 3 to 5, schematic views of a method of making a package according to the present invention are shown. Referring to FIGS. 3 and 4 together, first, a substrate 11 is provided. The substrate 11 may be a circuit board. Next, a semiconductor element 12 having a first surface 121 is provided, in which a plurality of bumps 122 and a ring structure 123 are disposed on the first surface 121, and the bumps 122 are outside the ring structure 123. Preferably, the ring structure 123 is of a material (for example, tin) which can be welded in a reflow process. The semiconductor element 12 is disposed on the substrate 11 through the bumps 122 and the ring structure 123.

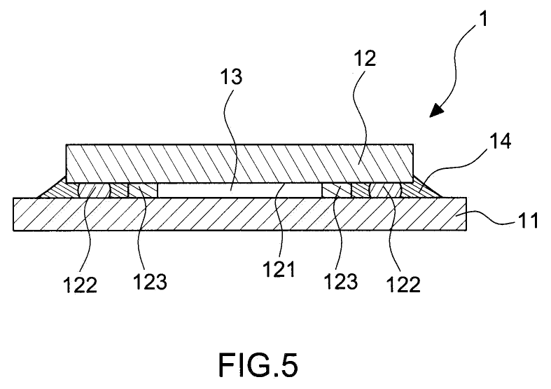

The ring structure 123 of the semiconductor element 12 and the substrate 11 define a closed space 13. Then, the bumps 122 electrically connect the substrate 11 and the semiconductor element 12 by utilizing a reflow process, and the ring structure 123 is welded between the substrate 11 and the semiconductor element 12. In this embodiment, the semiconductor element 12 is a chip, such as an integrated circuit (IC) chip or an application specific IC chip. Or, the semiconductor element 12 is an MEMS element, such as an optical element or an MEMS microphone element. Referring to FIG. 5, finally, an underfill 14 is filled between the substrate 11 and the semiconductor element 12, covering the bumps 122 and out of the ring structure 12, thus completing the package 1 of the present invention.

Referring to FIG. 5, a schematic view of a package according to a first embodiment of the present invention is shown. The package of the first embodiment includes a substrate 11, a semiconductor element 12, and an underfill 14. The substrate 11 may be a circuit board. The semiconductor element 12 has a first surface 121, in which a plurality of bumps 122 and a ring structure 123 are disposed on the first surface 121, and the bumps 122 are outside the ring structure 123. Preferably, the ring structure 123 is of a material (for example, tin) which can be welded in the reflow process.

The semiconductor element 12 is disposed on the substrate 11 through the bumps 122 and the ring structure 123. The bumps 122 electrically connect the substrate 11 and the semiconductor element 12, and the ring structure 123 is welded between the substrate 11 and the semiconductor element 12, so that the substrate 11 and the ring structure 123 of the semiconductor element 12 define a closed space 13. In this embodiment, the semiconductor element 12 is a chip, such as an IC chip or an application specific IC chip. The underfill 14 is filled between the substrate 11 and the semiconductor element 12, covering the bumps 122 and out of the ring structure 123.

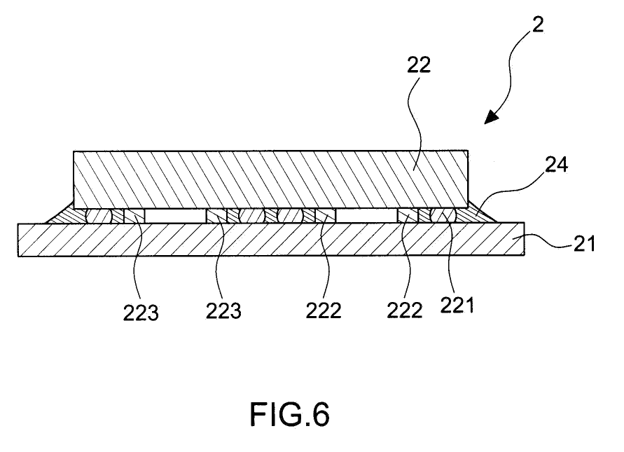

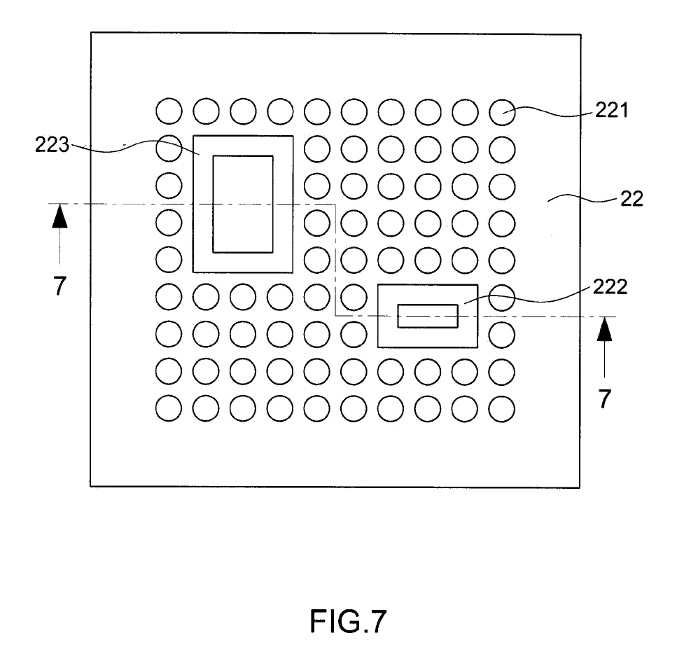

Referring to FIGS. 6 and 7, schematic views of a package according to a second embodiment of the present invention are shown. The package 2 of the second embodiment includes a substrate 21, a semiconductor element 22, and an underfill 24. Different from the above package 1 of the first embodiment, in the second embodiment, the semiconductor element 22 has a plurality of bumps 221 and two ring structures 222, 223, in which the bumps 221 are outside the ring structures 222, 223. The underfill 24 is filled between the substrate 21 and the semiconductor element 22, covering the bumps 221 and out of the ring structures 222, 223, so as to form the package 2.

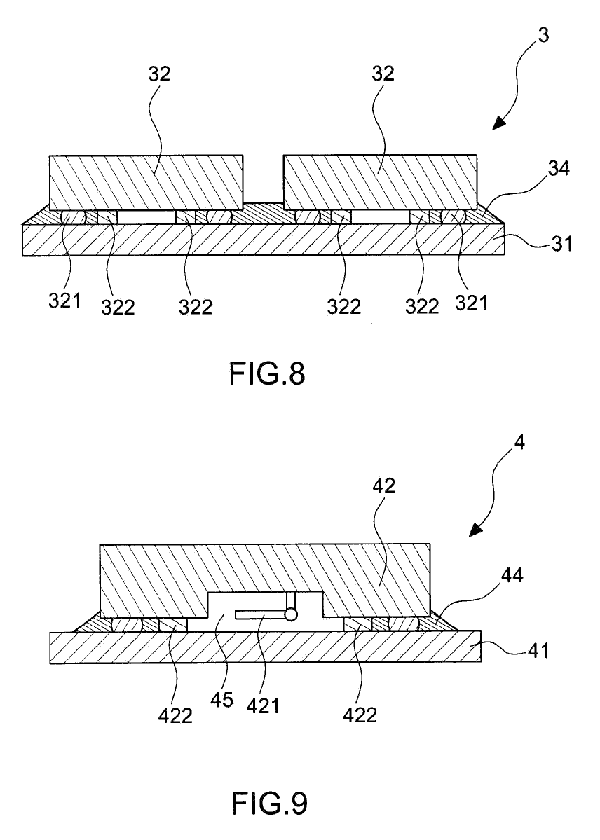

Referring to FIG. 8, a schematic view of a package according to a third embodiment of the present invention is shown. The package 3 of the third embodiment includes a substrate 31, two semiconductor elements 32, and an underfill 34. Different from the above package 1 of the first embodiment, the package 3 of the third embodiment has two semiconductor elements 32, and each semiconductor elements 32 has a plurality of bumps 321 and a ring structure 322. The bumps 321 are outside the ring structure 322. The underfill 34 is filled between the substrate 31 and the semiconductor elements 32, covering the bumps 321 and out of the ring structures 322, so as to form the package 3 of the third embodiment.

Referring to FIG. 9, a schematic view of a package according to a fourth embodiment of the present invention is shown. The package 4 of the fourth embodiment includes a substrate 41, a semiconductor element 42, and an underfill 44. Different from the above package 1 of the first embodiment, in the package 4 of the fourth embodiment, the semiconductor element 42 is an MEMS element. In this embodiment, the MEMS element is an optical element. The optical element has a movable element 421. The movable element 421 is disposed on a surface of the semiconductor element 42, and is located in a closed space 45 defined by the substrate 41 and the ring structure 422 of the semiconductor element 42 (the optical element), so that the movable element 421 can move within the closed space 45.

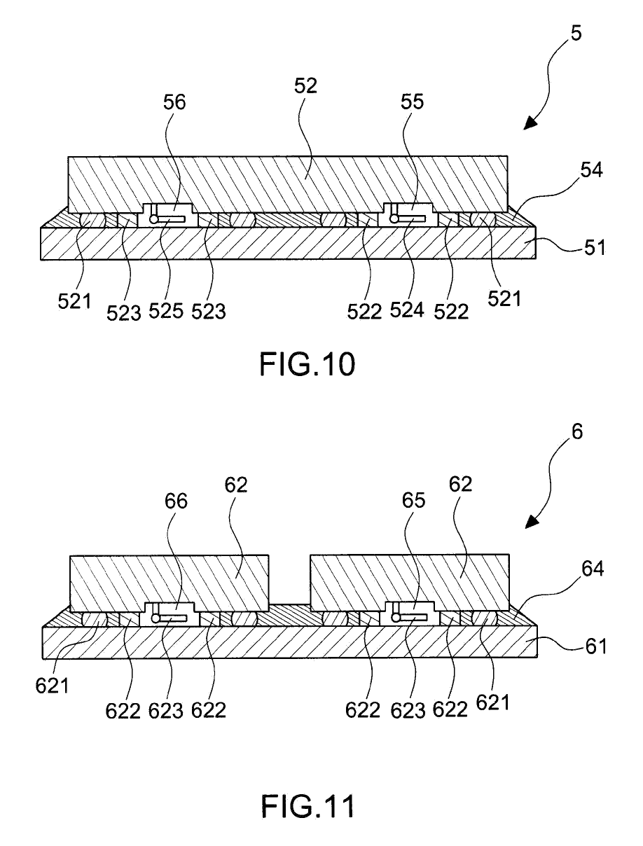

Referring to FIG. 10, a schematic view of a package according to a fifth embodiment of the present invention is shown. The package 5 of the fifth embodiment includes a substrate 51, a semiconductor element 52, and an underfill 54. The semiconductor element 52 has a plurality of bumps 521 and two ring structures 522, 523, in which the bumps 521 are outside the ring structures 522, 523. The semiconductor element 52 has a plurality of movable elements 524, 525. The movable elements 524, 525 are respectively located in closed spaces 55, 56 defined by the substrate 51 and the ring structures 522, 523 of the semiconductor element 52. The underfill 54 is filled between the substrate 51 and the semiconductor element 52, covering the bumps 521 and out of the ring structures 522, 523, so as to form the package 5 of the fifth embodiment.

Referring to FIG. 11, a schematic view of a package according to a sixth embodiment of the present invention is shown. The package 6 of the sixth embodiment includes a substrate 61, two semiconductor elements 62, and an underfill 64. Different from the above package 5 of the fifth embodiment, the package 6 of the sixth embodiment has two semiconductor elements 62, and each semiconductor elements 62 has a plurality of bumps 621 and a ring structure 622. The bumps 621 are outside the ring structure 622. Each semiconductor element 62 has a movable element 623. The movable elements 623 are respectively located in closed spaces 65, 66 defined by the substrate 61 and the ring structures 622 of the semiconductor elements 62. The underfill 64 is filled between the substrate 61 and the semiconductor elements 62, covering the bumps 621 and out of the ring structures 622, so as to form the package 6 of the sixth embodiment.

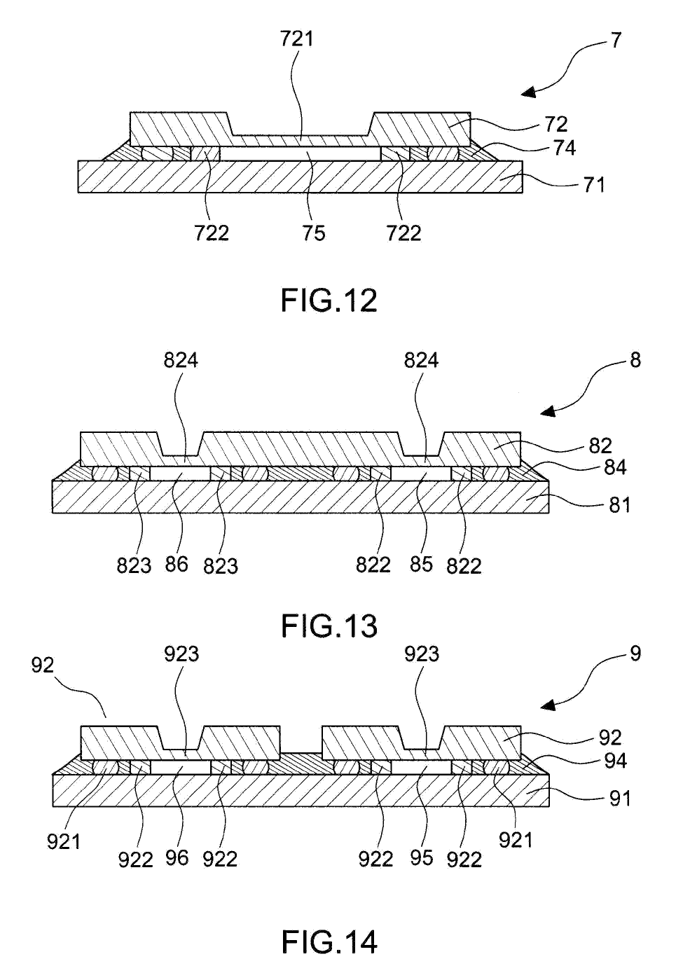

Referring to FIG. 12, a schematic view of a package according to a seventh embodiment of the present invention is shown. The package 7 of the seventh embodiment includes a substrate 71, a semiconductor element 72, and an underfill 74. Different from the package 4 of the fourth embodiment in FIG. 9, in the package 7 of the seventh embodiment, the semiconductor element 72 is an MEMS microphone element. The semiconductor element 72 (the MEMS microphone element) has a diaphragm 721 located at a corresponding position on a closed space 75 defined by the substrate 71 and the ring structure 722 of the semiconductor element 72 (the MEMS microphone element). The closed space 75 provides a space for the vibration of the diaphragm 721.

Referring to FIG. 13, a schematic view of a package according to an eighth embodiment of the present invention is shown. The package 8 of the eighth embodiment includes a substrate 81, a semiconductor element 82, and an underfill 84. The semiconductor element 82 has a plurality of bumps 821 and two ring structures 822, 823, in which the bumps 821 are outside the ring structures 822, 823. The semiconductor element 82 has a plurality of diaphragms 824, 825. The diaphragms 824, 825 are respectively located at corresponding positions on closed spaces 85, 86 defined by the substrate 81 and the ring structures 822, 823 of the semiconductor element 82. The underfill 84 is filled between the substrate 81 and the semiconductor element 82, covering the bumps 821 and out of the ring structures 822, 823, so as to form the package 8 of the eighth embodiment.

Referring to FIG. 14, a schematic view of a package according to a ninth embodiment of the present invention is shown. The package 9 of the ninth embodiment includes a substrate 91, two semiconductor elements 92, and an underfill 94. Different from the above package 8 of the eighth embodiment, the package 9 of the ninth embodiment has two semiconductor elements 92, and each elements 92 has a plurality of bumps 921 and a ring structure 922, and the bumps 921 are outside the ring structure 922. Each semiconductor element 92 has a diaphragm 923. The diaphragms 923 are located at corresponding positions on closed spaces 95, 96 defined by the substrate 91 and the semiconductor elements 92, so as to make the diaphragms 923 move within the closed spaces 95, 96. The underfill 94 is filled between the substrate 91 and the semiconductor elements 92, covering the bumps 921 and out of the ring structures 922, so as to form the package 9 of the ninth embodiment.

In a package made by the packaging method of the present invention, a closed space is formed between the substrate and the ring structure of the semiconductor element. Therefore, the packaging method of the present invention is not only applicable for a common flip chip package, but also for an MEMS element, since the closed space formed between the substrate and the semiconductor element may be provided for the movement of the movable elements and the diaphragm in the MEMS element.

Moreover, in the package of the present invention, the semiconductor element is directly disposed on the substrate through the bumps and the ring structure, and is electrically connected to the substrate through the bumps, so a wire bonding process is not required. Therefore, the packaging step of the present invention is simplified, thus reducing the packaging time and the production cost.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A package, comprising:
a substrate;
a semiconductor element, having a first surface, wherein a plurality of bumps and at least one ring structure are disposed on the first surface, and the bumps are outside the ring structure; the semiconductor element is disposed on the substrate through the bumps and the ring structure; the ring structure of the semiconductor element and the substrate define a closed space; the bumps electrically connect the substrate and the semiconductor element; and
an underfill, filled between the substrate and the semiconductor element, covering the bumps and out of the ring structure.

2. The package according to claim 1, wherein the substrate is a circuit board.

3. The package according to claim 1, wherein the semiconductor element is a chip.

4. The package according to claim 3, wherein the chip is an integrated circuit (IC) chip.

5. The package according to claim 4, wherein the IC element is an application specific IC chip.

6. The package according to claim 1, further comprising at least one movable element disposed on the first surface of the semiconductor element, and located in the closed space.

7. The package according to claim 1, wherein the semiconductor element is a micro electro-mechanical systems (MEMS) element.

8. The package according to claim 7, wherein the MEMS element is an optical element.

9. The package according to claim 7, wherein the MEMS element is an MEMS microphone element.

10. The package according to claim 7, wherein the semiconductor element has a diaphragm located on the closed space.

11. The package according to claim 1, wherein the material of the ring structure is a weldable material.

12. The package according to claim 11, wherein the material of the ring structure is tin.

13. A method of making a package, comprising the steps of:
(a) providing a substrate;
(b) providing a semiconductor element having a first surface, wherein a plurality of bumps and at least one ring structure are disposed on the first surface, and the bumps are outside the ring structure;
(c) disposing the semiconductor element on the substrate, wherein the ring structure of the semiconductor element and the substrate define a closed space, and the bumps electrically connect the substrate and the semiconductor element; and
(d) filling an underfill between the substrate and the semiconductor element, wherein the underfill covers the bumps and is out of the ring structure.

14. The method according to claim 13, wherein in Step (c), the bumps electrically connect the substrate and the semiconductor element by utilizing a reflow process, and the ring structure is welded to the substrate and the semiconductor element.

15. The method according to claim 14, wherein a material of the ring structure is tin.
